(19) United States
(12) Patent Application Publication
(10) Pub. No.: US 2007/0231108 A1
(43) Pub. Date: Oct. 4, 2007

(54) Method and apparatus for transferring wafers

(75) Inventor: Alpay Yilmaz, San Jose, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/397,263

(22) Filed: Apr. 4, 2006

(51) Int. Cl. H01L 21/677

(52) U.S. Cl. 414/217

(57) ABSTRACT

A method and apparatus for transferring wafers within a processing chamber is disclosed. To save space, wafers can be placed perpendicularly in random access input and random access output stations adjacent to the processing chamber. To move the wafers from the random access input station to the processing chamber and then to the random access output station, a rotatable gripper is provided. The gripper normally lies in a plane perpendicular to the wafer chuck, but the gripper is rotatable about ±90° clockwise and about ±90° counterclockwise so that the wafers can be gripped in the random access input station, released onto the wafer chuck, and re-gripped and released into the random access output station.

### BACKGROUND OF THE INVENTION

1. Field of the Invention

Embodiments of the present invention generally relate to a method and apparatus for transferring wafers within a processing system whereby the wafers lie in a plane perpendicular to that of the processing chamber and can be stored in a separate compartment.

2. Description of the Related Art

Moving wafers between processing chambers at a greater speed is essential to lessen downtime and increase productivity in a semiconductor processing line. The more time it takes to transfer a wafer between and into processing chambers, the more time the processing chamber sits idle. An idle processing chamber can result in great financial losses over time.

One way of causing downtime is to have numerous degrees of movement for a wafer. U.S. Pat. No. 6,822,413 to Simondet discloses a transportation system for wafers in which a sensor is present on the wafer moving mechanism that can auto calibrate. The wafer robot pivots around several axes while keeping the wafer in the same plane as the wafer chuck. Because the wafer is in a plane horizontal to the wafer chuck, the processing system will be longer and the wafer will need to travel a greater distance through the system. The robot, because of its several axes of rotation, will require a large space in which to rotate. The arm itself is contained in its own separate chamber, which increases cost and space requirements.

U.S. Pat. No. 6,773,543 to Summers discloses a system for removing and transporting individual die from a wafer. A pickhead arm rotates 90° clockwise so that a removal nozzle is perpendicular to the wafer. The nozzle contacts the wafer on a specific die and then vacuum is applied. The vacuum secures the die to the nozzle so that the die can be removed. While removing a die from the wafer, the nozzle touches the face of the die which can lead to contamination.

U.S. Pat. No. 6,662,673 to Olgado discloses a conventional transfer robot in which a single arm pivots about several axes of rotation and extends to the wafer. The arm comprises a plurality of fingers wherein the fingers grip the wafer on the face of the wafer. The conventional robot runs the risk of contaminating the wafer by touching the wafer on its face. The robot also requires a large amount of space. Also, keeping the wafer in the same plane as the chuck will require more space.

U.S. Pat. No. 6,366,830 to Bacchi et al. discloses a robot assembly for transferring wafers that rotates about three separate axes of rotation. The robot grabs the wafer on the bottom at a position near the center of the wafer. The robot has at least two separate arms that operate on separate wafers, but each arm is interconnected through a common base housing. By holding the wafer along the bottom of the wafer, contamination of the underside of the wafer is a risk. Also, keeping the wafer in the same plane as the chuck will require more space.

U.S. Pat. No. 5,947,677 to Matsushima et al. discloses a cassette transfer mechanism. The cassette is a square shaped cassette and can hold 25 wafers. The cassette holder has sides, bottom support elements and a back surface supporting surface. When viewed from the side, the cassette holder looks like a triangle. The holder elements are not movable toward each other. Also, keeping the wafer in the same plane as the chuck will require more space.

U.S. Pat. No. 5,944,476 to Bacchi et al. discloses a robot assembly for transferring wafers that rotates about three separate axes of rotation. The robot has a hand on the end of the arm. The hand is forked with two distal ends that have vacuum pressure outlets so that vacuum pressure may be applied so that the wafer can be held in position. The forked hand grips the wafer on its face and runs the risk of contaminating the wafer. Also, keeping the wafer in the same plane as the chuck will require more space.

U.S. Pat. No. 5,271,702 to Dobbs et al. discloses transferring a wafer to a processing station by rotating a carousel to the cassette. A manipulator arm is then moved vertically to the wafer. The gripper opens and the arm rotates to the cassette location that overlaps the wafer. Once the arm is rotated, the gripper closes and the arm rotates out of the carousel to the transport position. The processing station door is opened and the arm is moved vertically to the processing station. The arm then rotates, the gripper opens, the arm rotates again out of the processing station, and the processing station door is closed. The gripper comprises at least two circular holders, one of which is in a fixed position and the other of which is movable. The movable holder moves outward as a wafer is placed into the gripper. Once the diameter of the wafer passes the grippers, the movable gripper moves back inward to secure the wafer.

U.S. Pat. No. 5,040,484 to Mears et al. discloses a device for transporting wafers in which a plurality of fingers grip the wafer along its periphery. The fingers are resilient and are machined to conform to the wafer so that a notch is formed. The wafer rests within the notch so that the periphery, bottom and possibly the top of the wafer are touched by the fingers. The fingers do not appear to rotate. By touching the wafer on the top and bottom, the wafer can become contaminated. Also, keeping the wafer in the same plane as the chuck will require more space.

There is a need in the art to provide effective transfer of wafers between chambers. There is also a need in the art to utilize less space for transfer chambers and processing chambers.

### SUMMARY OF THE INVENTION

The present invention generally comprises a method and apparatus for transferring wafers within a processing system.

The first preferred embodiment involves an apparatus. The apparatus has a vacuum chamber, a wafer chuck in the vacuum chamber, a random access input station, a random access output station, and a rotatable wafer gripper. The wafer chuck is movable between a lowered position and a raised position and has a planar wafer receiving surface. The random access input station is capable of holding one or more wafers perpendicularly to the planar wafer receiving surface. The random access output station is capable of holding the one or more wafers perpendicularly to the planar wafer receiving surface. The rotatable wafer gripper is capable of moving the one or more wafers from a plane perpendicular to the planar surface to a plane parallel with the planar surface.

A second embodiment also involves an apparatus. The apparatus has a metrology chamber, a wafer chuck, and a rotatable, extendable wafer gripper. The rotatable, extendable gripper is capable of moving one or more wafers from a plane perpendicular to the wafer chuck to a plane parallel to the wafer chuck.

A third embodiment involves a method of transferring wafer. The method involves gripping a wafer in a random access input station with an extendable gripper, rotating the gripper about 90° so that the gripped wafer is in a plane parallel to a planar surface or a wafer chuck, releasing the gripped wafer from the gripper onto the planar surface, processing the released wafer, re-gripping the released wafer after the processing with the gripper on the wafer perimeter, rotating the gripper about 90° so that the gripped wafer is in a plane perpendicular to the planar surface of the wafer chuck; and releasing the re-gripped wafer in a random access output station. The gripper has two extendable arms that grip the wafer and is located within a central processing station.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a front view of the apparatus with extendable gripper arms in the initial position.

FIG. 2 is a front view of the apparatus with the gripper arms in an extended position to pick up a wafer.

FIG. 3 is a front view of the apparatus with the gripper arms holding the wafer in a retracted position to deliver the wafer to the chuck.

FIG. 4 is a front view of the apparatus of the wafer being delivered to the chuck.

FIG. 5 is a front view of the apparatus with the wafer on the chuck in the processing position.

FIG. 6 is a front view of the apparatus with the gripper arms in an extended position to release the wafer into the random access output station.

FIG. 7 is a top view of FIG. 2.

### DETAILED DESCRIPTION

The present invention describes a method and apparatus for transferring wafers within a processing system. To save space in a processing line it would be beneficial to place wafers in a plane perpendicular to the processing plane during transfer between chambers. Unfortunately, it is not easy to move a wafer from a horizontal processing position to a perpendicular transfer position without contaminating the wafer by touching it on its face. Flipping the wafers to a plane perpendicular to the processing plane could easily involve as much transfer chamber space as is normally required for a horizontal wafer transfer chamber. The instant invention allows transfer of wafers between chambers while conserving space and limiting the size of transfer chambers.

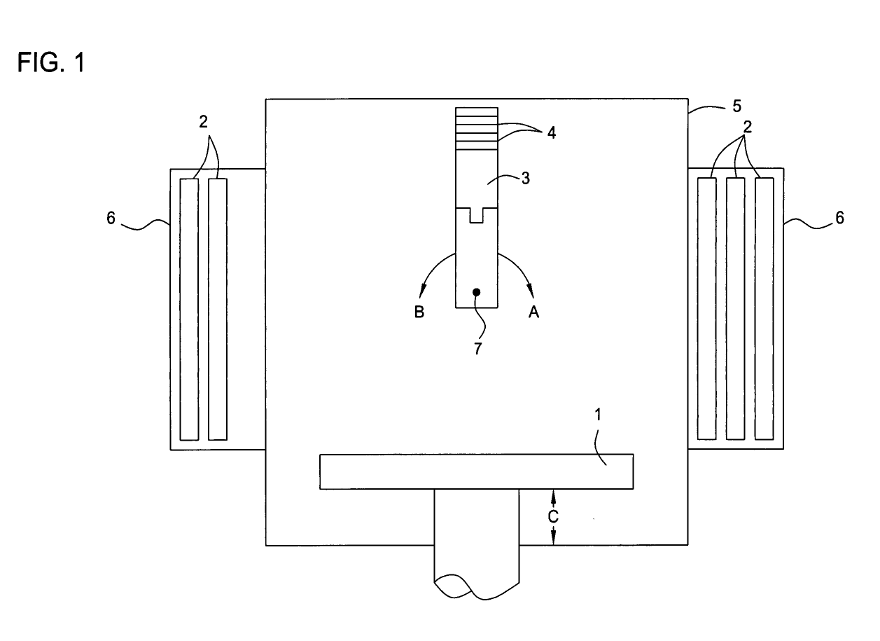

FIG. 1 is a front view of an apparatus of the instant invention with the extendable gripper arms 3 in an initial position. For clarity, only one gripper arm 3 is shown. The apparatus comprises a chamber 5, a wafer chuck 1, and the gripper arms 3 with gripper ends 4. Adjacent to the chamber 5 are random input/output stations 6. Initially, the wafer chuck 1 is in a lowered position while the gripper arms 3 lie in a plane perpendicular to the plane of the wafer chuck face. The gripper arms 3 are rotatable about an axis 7. The gripper arms can rotate clockwise as indicated by arrow A and counterclockwise as indicated by arrow B. The wafer chuck can move up and down as indicated by arrow C.

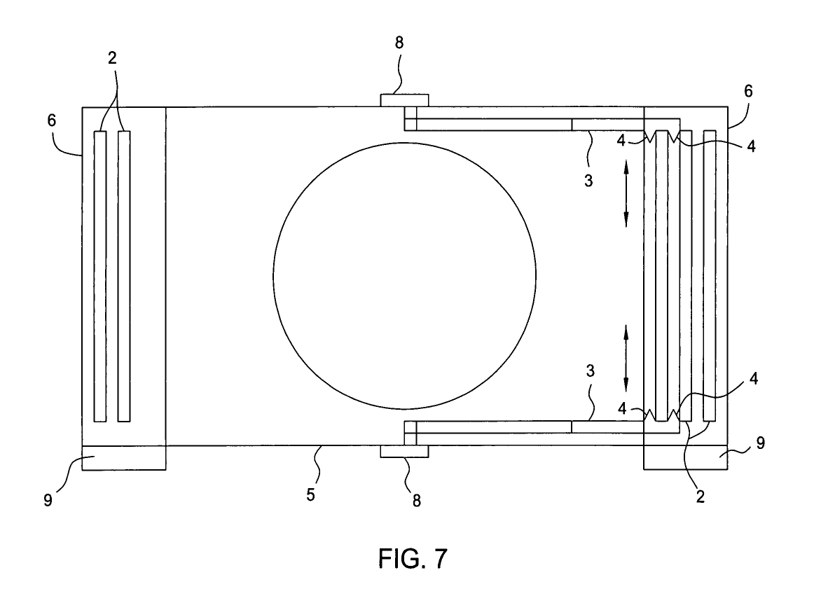

The random input/output stations 6 are randomly supplied with wafers through a door 9 (see FIG. 7). Wafers 2 can be placed in any order into the random input/output stations 6 and removed in any order. The gripper arms 3 are extendable into the random input/output stations 6. The gripper arms 3 can extend into the random input/output stations 6 to grip or release the wafer 2 from any point within the station. Once the wafer 2 is gripped, the gripper arms 3 retract so that the wafer can be rotated within the processing chamber 5. When the wafer 2 is returned to the random input/output station 6, the gripper arm extends into the station 6, releases the wafer 2, and then retracts so that the gripper arms 3 can rotate within the chamber 5.

The random input/output stations 6 are random in the sense that they can be randomly accessed through door 9. The gripper arms 3 are only capable of accessing the wafer 2 closest to the chamber 5.

The griper arms 3 are rotated by a gripper rotator 8. The gripper rotator 8 can be any mechanism capable of providing controlled rotational movement of the gripper arms 3. Examples of conventional rotation mechanisms include motors, gears, and pulleys.

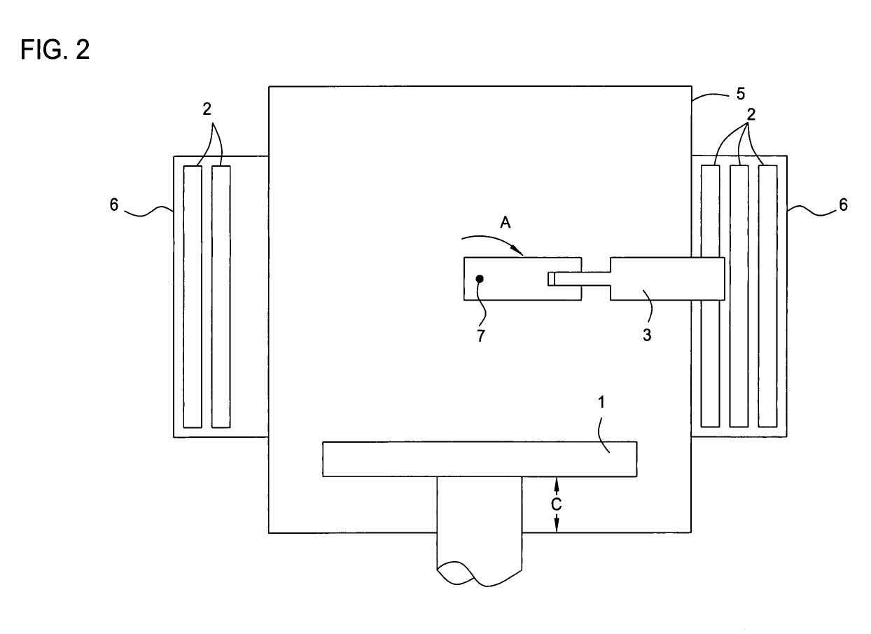

In order to pick up a wafer 2 form the random access input/output station 6, the gripper arms 3 must rotate about 90° along the path shown by the arrow A. Once the gripper arms 3 have rotated, the arms are in position to pick up a wafer as shown in FIGS. 2 and 7. The gripper arms 3 can extend and move laterally in order to grip the wafer. The gripper arms 3 are moved in a direction so that the arms 3 are farther apart as the gripper ends 4 surround the wafer 2. Once the gripper ends are lined up with the wafer, the gripper arms 3 are moved closer together so that the wafer 2 rests between the gripper ends 4 provided on each gripper arm 3.

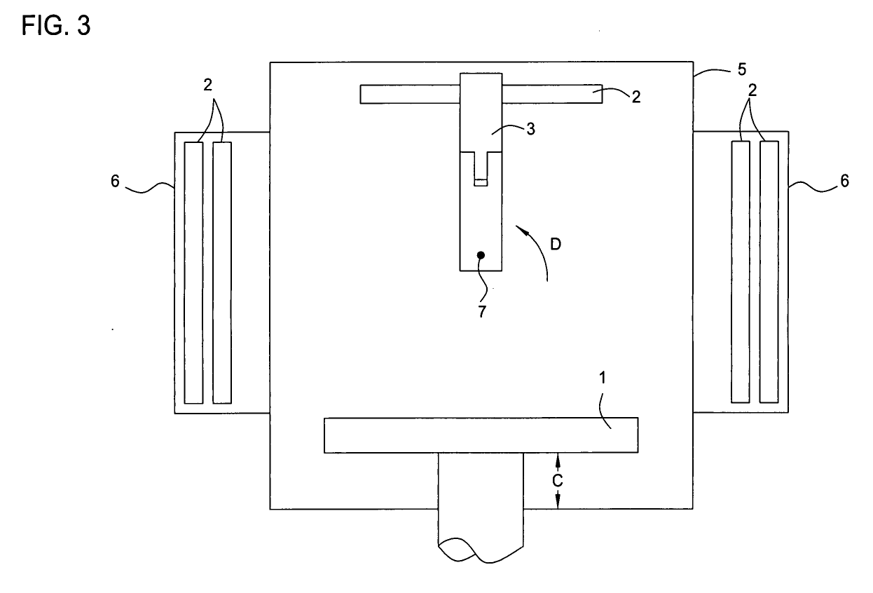

Once the wafer 2 has been gripped by the gripper ends 4 on the gripper arms 3, the gripper arms 3 retract and rotate about 90° counterclockwise to the initial position shown in FIG. 3. The gripper arms 3 rotate as indicated by arrow D about the axis 7. As can be seen from FIG. 3, the wafer 2 is now in a plane parallel to the wafer chuck 1.

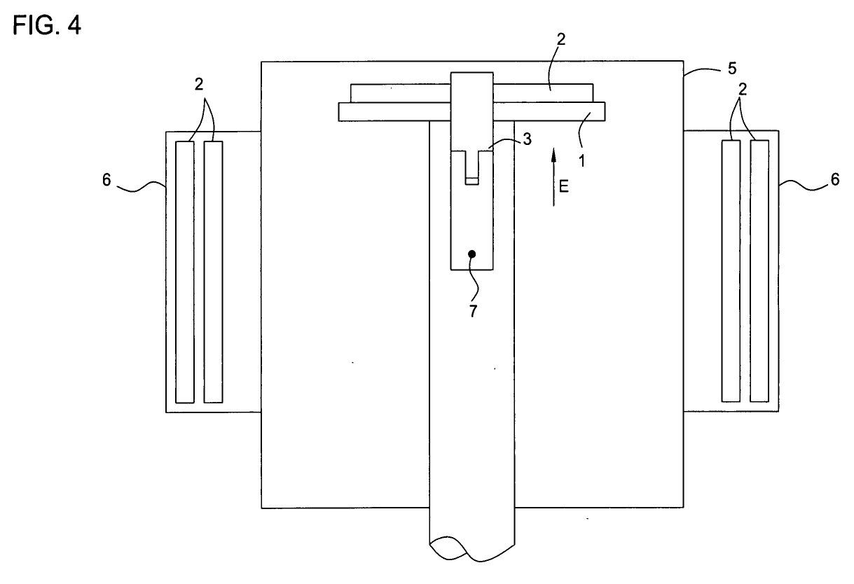

FIG. 4 shows the wafer chuck 1 in a raised position. The wafer chuck is raised as indicated by arrow E. Once raised, the wafer 2 rests on the wafer chuck 1 and the gripper arms 3 are moved apart to let go of the wafer 2.

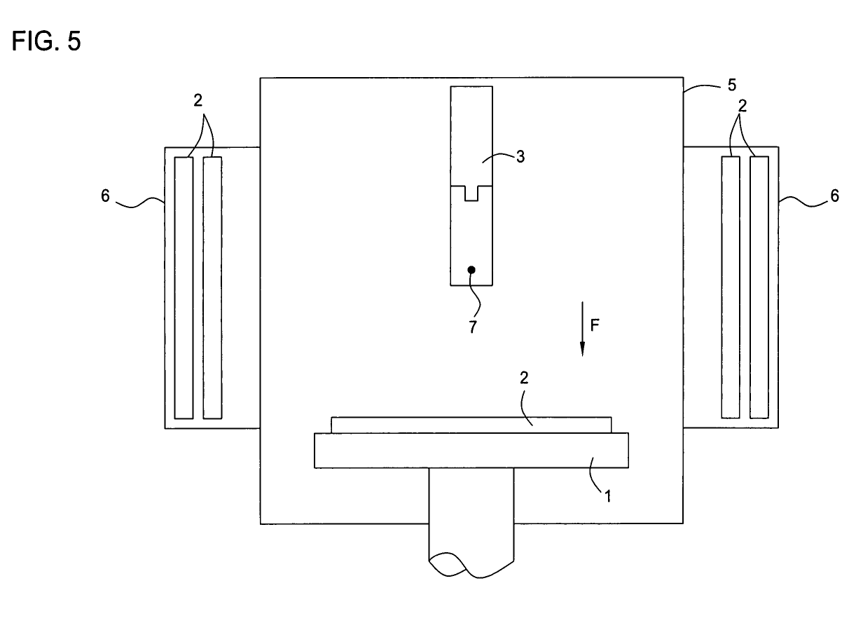

FIG. 5 shows the wafer chuck 1 back in a lowered position. The wafer chuck 1 is lowered as indicated by arrow F. The wafer 2 is on the wafer chuck 1 so that the wafer may be processed. Alternatively, the wafer chuck 1 could remain stationary and the gripper arms 3 could be lowered, with the wafer 2 remaining parallel to the wafer chuck 1 or both the wafer chuck 1 and the gripper arms 3 can move so that the wafer 2 can be placed on the wafer chuck 1.

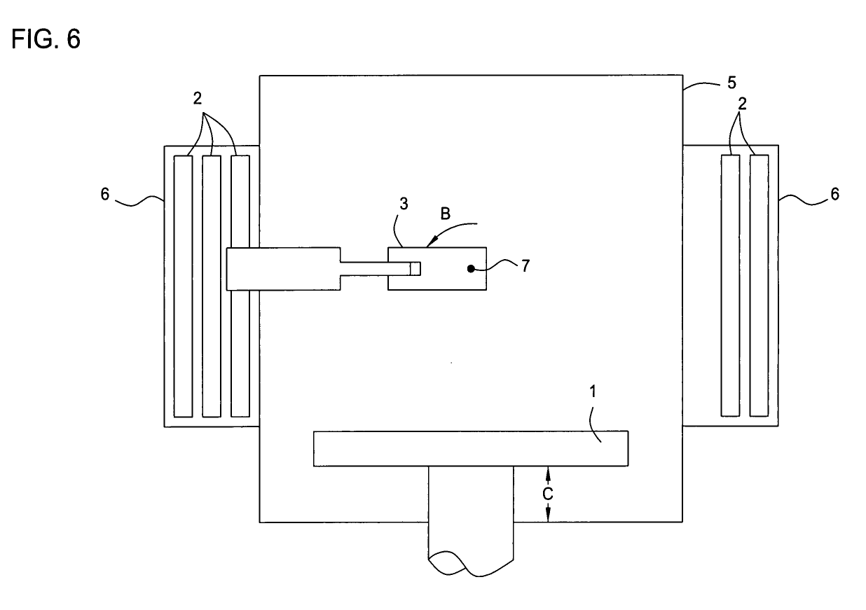

Once the wafer 2 has been processed, the wafer chuck 1 is raised to meet the gripper arms 3 as shown in FIG. 4. The wafer chuck 1 then lowers again and the griper arms 3 rotate about 90° counterclockwise and extend so that the wafer 2 is positioned in the random access input/output station 6 to exit the chamber 5 as shown in FIG. 6. The gripper arms are rotated about the axis 7 as shown by arrow B. Once the wafer 2 has been dropped off at the random access input/output station, the gripper arms 3 return to the initial position shown in FIG. 1 so that the process can begin again.

In the processing chamber, metrology, chemical vapor deposition (CVD), physical vapor deposition (PVD), chemical mechanical polishing (CMP), etching, or combinations thereof may occur.

While the foregoing is directed to embodiments of the present invention, other and further embodiments of the invention may be devised without departing from the basic scope thereof, and the scope thereof is determined by the claims that follow.

1. An apparatus comprising:
a vacuum chamber;
a wafer chuck in said vacuum chamber, said wafer chuck movable between a lowered position and a raised position and said wafer chuck having a planar wafer receiving surface;
a random access input station, said random access input station capable of holding one or more wafers perpendicularly to said planar wafer receiving surface;
a random access output station, said random access output station capable of holding the one or more wafers perpendicularly to said planar wafer receiving surface; and
a rotatable wafer gripper, capable of moving the one or more wafers from a plane perpendicular to said planar surface to a plane parallel with said planar surface.

2. The apparatus as claimed in claim 1, wherein said gripper comprises two arms.

3. The apparatus as claimed in claim 1, wherein said apparatus comprises one or more of a CVD chamber, metrology chamber, a PVD chamber, or an etch chamber.

4. The apparatus as claimed in claim 1, wherein said gripper comprises arms capable of moving closer together until said arms touch said wafer with sufficient force to enable said wafer to be lifted.

5. The apparatus as claimed in claim 1, wherein said gripper comprises arms capable of moving farther apart until said arms no longer touch said wafer.

6. The apparatus as claimed in claim 1, wherein said gripper comprises gripper ends for gripping said wafer.

7. An apparatus comprising:
a metrology chamber that includes a wafer chuck; and
a rotatable, extendable wafer gripper capable of moving one or more wafers from a plane perpendicular to said wafer chuck to a plane parallel to said wafer chuck.

8. The apparatus as claimed in claim 7, wherein said gripper comprises arms capable of moving closer together until said arms touch said wafer with sufficient force to enable said wafer to be lifted.

9. The apparatus as claimed in claim 7, wherein said gripper comprises arms capable of moving farther apart until said arms no longer touch said wafer.

10. The apparatus as claimed in claim 7, wherein said gripper comprises gripper ends for gripping said wafer.

11. The apparatus as claimed in claim 7, wherein said gripper comprises two arms.

12. A method of transferring wafers within a processing system comprising:
gripping a wafer in a random access input station with a gripper located within a central processing station, wherein said gripper comprises two arms that grip said wafer;
rotating the gripper about 90° so that the gripped wafer is in a plane parallel to a planar surface of a wafer chuck;
releasing the gripped wafer from the gripper onto the planar surface;
processing the released wafer;
re-gripping the released wafer after the processing with the gripper on the wafer perimeter;
rotating said gripper about 90° so that the gripped wafer is in a plane perpendicular to the planar surface of the wafer chuck; and
releasing said re-gripped wafer in a random access output station.

13. The method as claimed in claim 12, wherein said gripper comprises two arms.

14. The method as claimed in claim 13, wherein said gripping said wafer comprises moving said arms closer together until said arms touch said wafer with sufficient force to enable said wafer to be lifted.

15. The method as claimed in claim 13, wherein said releasing said wafer comprises moving said arms farther apart until said arms no longer touch said wafer.

16. The method as claimed in claim 12, wherein said processing comprises one or more of CMP, PVD, CVD, metrology, and etching.

17. The method as claimed in claim 12, further comprising raising the wafer chuck to meet the wafer after the wafer, lowering said wafer chuck with said wafer thereon for processing, raising said wafer chuck to said gripper arms after processing is completed, and lowering said wafer chuck after said gripper re-grips said wafer.

18. The method as claimed in claim 12, Wherein said gripper comprises gripper ends for gripping said wafer.

19. The method as claimed in claim 12, further comprising lowering said wafer to said wafer chuck while said wafer is maintained parallel to said planar surface.

20. The method as claimed in claim 12, wherein said wafer chuck raises to meet said wafer while said wafer is lowered to said wafer chuck.
